(19) United States
(12) Patent Application Publication
(10) Pub. No.: US 2026/0314814 A1
(43) Pub. Date: Oct. 15, 2026

(54) USER INTERFACE FOR AN ADJUSTABLE ARTICLE OF FURNITURE

(71) Applicant: LINAK A/S, Nordborg (DK)

(72) Inventors: Steffen Guldhammer Lauridsen, Sønderborg (DK); Norbert Klinke, Augustenborg (DK)

(21) Appl. No.: 19/482,150

(22) PCT Filed: May 3, 2024
(86) PCT No.: PCT/DK2024/050103

§ 371 Date: Nov. 6, 2025

(30) Foreign Application Priority Data
May 8, 2023 (DK) PA202330017

(51) Int. Cl. A47B 9/04; H05K 1/02; H05K 1/181

(52) U.S. Cl. CPC A47B 9/04; H05K 1/0278; H05K 1/181; A47B 2200/0056; A47B 2200/0062; A47B 2220/0091; H05K 2201/09027; H05K 2201/09063; H05K 2201/09072; H05K 2201/10151

(57) ABSTRACT

A user interface for adjusting an adjustable article of furniture comprises a housing firmly fastened to a movable part of the article of furniture, a printed circuit board (26) arranged in the housing and comprising a first section and a second section, at least one mechanically operated switch (27, 28) mounted on the first section, and an electronic sensor device (37) for detecting mechan-ical movement and mounted on the second section, which is firmly fastened to the housing. The printed circuit board (26) is provided with at least one cut-out (42, 53) arranged between the first and second section and defining a contin-uous mechanical path (54) through the circuit board from the switch (27, 28) to the electronic sensor device (37), and the first section of the circuit board is connected mechanically to the housing through the continuous mechanical path and the second section of the circuit board.

### TECHNICAL FIELD

The invention relates to a user interface for adjusting an adjustable article of furniture comprising an electric actuator system, and further to an electric actuator system, and to an adjustable article of furniture.

### BACKGROUND

Many types of adjustable article of furniture, such as hospital and care beds, leisure beds and chairs, and height-adjustable tables, use electric actuator systems. As an example, a common height-adjustable table comprises a frame to which a tabletop is mounted. The frame is attached to one end of at least one linear actuator in the form of a lifting column. A foot is mounted to the other end of the lifting column. The height-adjustable table further comprises a controller (control box), which in the present application refers to the electronics that switch the current to be supplied to the motor of the linear actuator to drive the lifting column(s).

Additionally, the height-adjustable table comprises a user interface, which in the present application refers to e.g. an operating panel that allows the user to activate the functions of the height-adjustable table, such as adjusting the height of the table to a higher or lower position. Possible technical means for activation could, as in the prior art, be push buttons, touch buttons, etc. The user interface will often be arranged on the tabletop.

As examples of lifting columns for height-adjustable tables, reference is made to WO/2004/040169 A1 and WO 2009/033486 A1 both LINAK A/S.

A common challenge when adjusting a piece of furniture, either relative to the floor or relative to other parts of said piece of furniture, is the risk of unintended squeezing of persons or objects. Thus, it would be critical if a body part of a person was squeezed during the adjustment of a height-adjustable table.

Furthermore, it is unfortunate if the furniture inflicts damage to the surroundings and/or is damaged hitting an infrangible object, e.g. a windowsill or a cable tray. Thus, it is desirable that a height-adjustable table is equipped with an arrangement for squeeze protection.

DE 10 2006 038 558 A1, Vibradorm GmbH, discloses a squeeze protection device utilizing an accelerometer electronic device to determine rapid changes in the movement. The application suggests several different placements of the accelerometer with the height-adjustable table, e.g. arranged with the tabletop, in or at the lifting column, or with one of the feet for carrying the lifting columns. However, the solution requires a wired connection especially for the purpose between the accelerometer device and the control. The general drawback of wires is cost and that wires are fragile which could set the squeeze protection out of order without warning the user.

A squeeze protection device that solves the problem of wiring has been disclosed where an accelerometer device is arranged directly with the controller or with a dongle that easily can be plugged into a port in the controller. However, if the controller housing itself is not fixed to a part of the height adjustable table, e.g. just being arranged loose in a cable tray, the squeeze protection will not work. The risk of injury will remain.

### SUMMARY

Therefore, it is an object of embodiments of the invention to provide an arrangement for squeeze protection that avoids additional wiring between the squeeze protection device and the controller, thereby minimizing the mentioned risks and at the same time reducing costs.

According to embodiments of the invention the object is achieved in a user interface for adjusting an adjustable article of furniture comprising an electric actuator system, the user interface comprising a housing configured to be firmly fastened mechanically to a movable part of said adjustable article of furniture, a printed circuit board arranged in the housing and comprising a first section and a second section, at least one mechanically operated switch for activating the adjustment of the adjustable article of furniture, said switch being mounted on the first section of said printed circuit board, and an electronic sensor device for detecting mechanical movement, said sensor device being mounted on the second section of said printed circuit board, wherein said second section of the printed circuit board is firmly fastened to the housing. The printed circuit board is provided with at least one cut-out arranged between said first section and said second section and defining a continuous mechanical path through the printed circuit board from the at least one mechanically operated switch to the electronic sensor device, and the first section of the printed circuit board is connected mechanically to the housing through said continuous mechanical path and said second section of the printed circuit board.

Arranging the electronic sensor device for detecting mechanical movement on the printed circuit board of the user interface saves the cost of a separate wired connection and a separate housing for the sensor device and prevents the squeeze protection from being set out of order without warning the user. However, when the electronic sensor device is arranged on the same printed circuit board as the at least one mechanically operated switch, the operation of this switch can generate mechanical noise in the form of bending of the printed circuit board or vibrations in the board, which can be transmitted through the board between the two sections and detected by the sensor device. This may cause a false detection of squeezing with the result that the adjustment of the table is unintentionally stopped.

By arranging at least one cut-out between the two sections in such a way that a continuous mechanical path through the printed circuit board from the at least one mechanically operated switch to the electronic sensor device is defined by the at least one cut-out, the noise level received at the electronic sensor device can be reduced, and the situation with false detection may be avoided or mitigated.

In an embodiment, the at least one cut-out defines the length of the continuous mechanical path. This means that the length of the path will be longer, thus resulting in a reduced transmission of noise.

Alternatively or additionally, the at least one cut-out may define the width of at least a part of the continuous mechanical path. This results in a narrower path in this part of the path, which leads to an increased flexibility of the printed circuit board and thus a reduced transmission of the mechanical noise.

In a further embodiment, on at least a part of the continuous mechanical path the printed circuit board has a reduced thickness that is defined by the at least one cut-out. Thus, the printed circuit board is provided with at least one cut-out arranged between said first section and said second section and defining a reduced thickness of said printed circuit board on at least a part of a continuous mechanical path through the printed circuit board from the at least one mechanically operated switch to the electronic sensor device. The reduced thickness of the board on this part of the path leads to an increased flexibility of the printed circuit board and thus a reduced transmission of the mechanical noise.

In an embodiment, the at least one cut-out comprises a single cut-out extending from an edge of said printed circuit board. This single cut-out extending from an edge of said printed circuit board, as well as said continuous mechanical path through the printed circuit board defined by said single cut-out, may have a spiral like shape. This shape ensures a relatively long and narrow path, which gives a good dampening of the noise.

In another embodiment, the at least one cut-out comprises two cut-outs, each one extending from a different edge of said printed circuit board. These two cut-outs may define a serpentine like shape of the continuous mechanical path through the printed circuit board. Also this shape ensures a relatively long and narrow path, which gives a good dampening of the noise.

In an embodiment, the electronic sensor device for detecting mechanical movement comprises an accelerometer. Alternatively or additionally, the electronic sensor device for detecting mechanical movement may comprise a gyroscope. These sensor types, or a combination thereof, are well suited for the detection of sudden speed changes of e.g. a tabletop of a height-adjustable table, and thus for use as a squeeze protection device.

As mentioned, the invention also relates to an electric actuator system comprising at least one linear actuator, a controller for controlling the at least one linear actuator, and a user interface as described above and connected to the controller. Further, the invention also relates to an adjustable article of furniture comprising an electric actuator system as described above.

### BRIEF DESCRIPTION OF THE DRAWINGS

Embodiments of the invention will now be described more fully below with reference to the drawings, in which:

FIG. 1 shows a perspective view of a height-adjustable table with an electric actuator system,

FIG. 2 shows an example of an electric actuator system, where a linear actuator is controlled by a control box,

FIGS. 3 and 4 show perspective views of a possible embodiment of an operating panel for an electric actuator system,

FIG. 5 shows a sectional view of the operating panel of FIGS. 3 and 4,

FIGS. 6a and 6b illustrates squeezing of an object by a height-adjustable table,

FIG. 7 shows an electric actuator system provided with a sensor for detecting mechanical movement,

FIG. 8 shows an electric actuator system with a sensor for detecting mechanical movement integrated into the operating panel,

FIG. 9 shows an example of a printed circuit board for an operating panel with switches and a sensor for detecting mechanical movement arranged on the board,

FIG. 10 shows a sectional view of an operating panel with a sensor for detecting mechanical movement arranged on the printed circuit board,

FIG. 11 shows the printed circuit board of FIG. 9 provided with a straight cut-out arranged between the switches and the sensor,

FIG. 12 shows a printed circuit board provided with a spiral shaped cut-out arranged around the sensor,

FIG. 13 shows a printed circuit board provided with a spiral shaped cut-out arranged around the switches,

FIG. 14 shows a printed circuit board provided with a cut-out in the board,

FIG. 15 shows a printed circuit board provided with two cut-outs defining a serpentine shaped path between the switches and the sensor,

FIG. 16 shows a different embodiment of a printed circuit board provided with two cut-outs defining a serpentine shaped path between the switches and the sensor,

FIGS. 17a and 17b show perspective views of the printed circuit board of FIG. 16, and

FIG. 18 shows an embodiment of a printed circuit board provided with a cut-out that reduces the thickness of a part of the board between the switches and the sensor.

### DETAILED DESCRIPTION

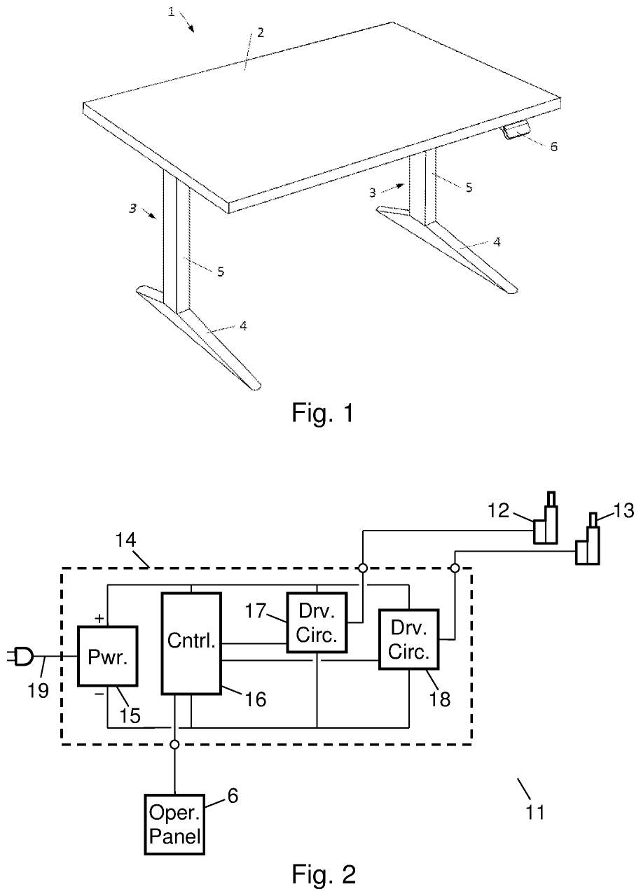

As an example of an adjustable article of furniture in which the invention can be used, FIG. 1 shows a perspective view of a height-adjustable table 1 comprising a tabletop 2. At each side of the height-adjustable table 1, a lifting column 3 comprising a linear actuator is mounted in a carrying frame (not shown) onto which the tabletop 2 is mounted. The other end of each lifting column 3 comprises a foot 4 on which the height adjustable-table 1 stands. Each lifting column 3 comprises two or three mutually telescopically arranged profiles. One profile 5 is stationary fixed to the foot 4 and one profile (not shown) is stationary fixed to the housing of the linear actuator. Each linear actuator, and thus each lifting column 3, is driven by means of an electric motor, which through a gear drives a spindle. The spindle is furnished with a spindle nut secured to the telescopically movable profile(s). The height-adjustment of the tabletop 2 is thus performed by an electric actuator system comprising the linear actuators of the lifting columns 3. The adjustment of the table is achieved by activating a user interface in the form of an operating panel 6.

Typically, an actuator system is controlled by a control box. An example of such an actuator system 11 is illustrated in FIG. 2. Via a cable, the linear actuators 12 and 13, i.e. the linear actuators of the lifting columns 3, are connected to a control box 14 that comprises at least a power supply 15, a controller 16 and driver circuits 17, 18 for the linear actuators 12 and 13. The driver circuits, and thus also the electric motor of each actuator, are controlled by control signals from the controller 16. Typically, the controller 16 comprises a microcomputer. The control box 14 is usually mounted onto the table comprising the linear actuators. The power supply 15 is typically connected to a mains AC supply net with a power cable 19, but a battery may also be used, either alone or in combination with a supply connected to a mains net. Finally, the control box 14 is connected to the operating panel 6 allowing the operation of the linear actuators to be controlled by a person in the vicinity of the table. Typically, the operating panel 6 can be attached to the underside of the tabletop 2, as it is illustrated in FIG. 1. The connection between the operating panel 6 and the control box 14 may be a wired connection as shown in FIG. 2, but a wireless communications system, such as a radio link or an infrared link, may also be used.

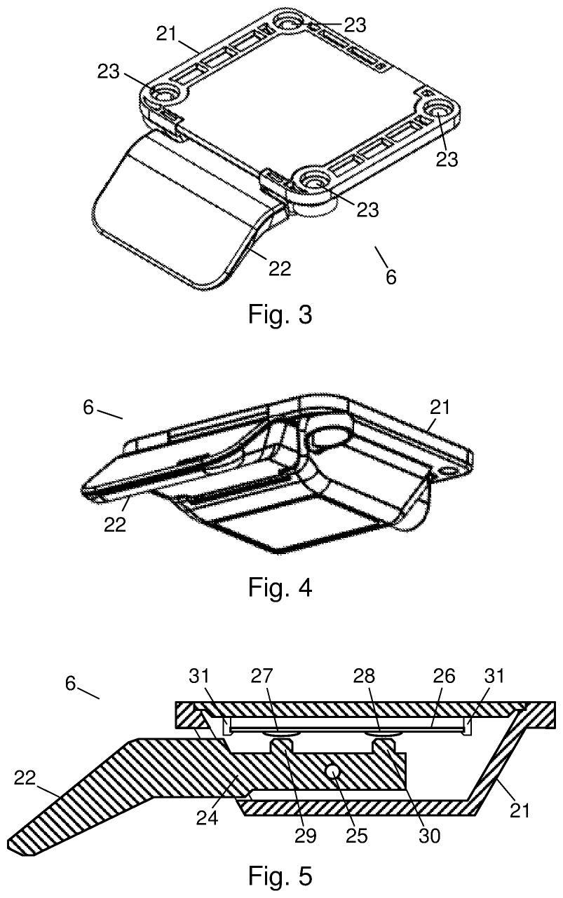

FIGS. 3 and 4 show perspective views of a possible embodiment of the operating panel 6. The operating panel 6 has a housing 21 and a paddle 22 for activating the linear actuators. As shown, the housing 21 is provided with four holes 23 for fastening the panel to the tabletop 2 by e.g. screws.

FIG. 5 shows a sectional view of the operating panel 6. As shown, the paddle 22 is the outer part of a lever 24 extending into the interior of the housing, where it as a rocker arm is mounted rotatable about an axis 25. Further, the housing 21 contains a printed circuit board 26, on which two dome switches 27 and 28 are arranged on the side facing the lever 24. A dome switch is a well-known switch type, where e.g. a metal dome, when the switch is pressed, collapses and connects two circuit traces placed below the dome, thereby establishing an electrical connection. The lever 24 has two extensions 29 and 30 arranged below the dome switches 27 and 28, respectively. When the paddle 22 is moved downwards, the remote end of the lever 24 with the extension 30 is moved upwards to activate the dome switch 28, causing the tabletop 2 to be lowered. Correspondingly, when the paddle 22 is moved upwards, the extension 29 is moved upwards to activate the dome switch 27, causing the tabletop 2 to be raised. Typically, the printed circuit board 26 is kept in place in the housing 21 by guides 31 arranged in the housing wall.

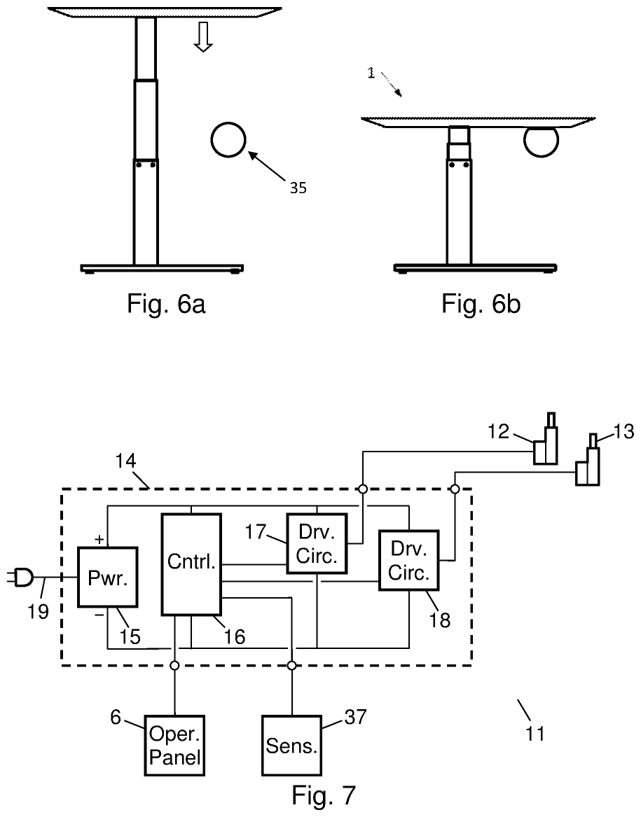

When adjusting the height of a height-adjustable table, or another adjustable article of furniture, there is a risk of an object getting squeezed. This could be a body part of a person using the table or an external object such as a windowsill or a cable tray. Such a situation is illustrated in FIGS. 6a and 6b, where FIG. 6a shows the table 1 being moved downwards towards an object 35. In FIG. 6b, the tabletop 2 has reached the object 35, which is now being squeezed.

To prevent this situation, the table is often equipped with an arrangement for squeeze protection. An expedient way of implementing squeeze protection is the use of an electronic sensor device for detecting mechanical movement, such as e.g. an accelerometer and/or a gyroscope, which is firmly fastened to the tabletop 2. When the tabletop 2 hits an object, there will be a sudden change in its movement, which will be detected by the sensor device, and a signal will be sent from the sensor device to the controller 16 causing the controller to stop the movement of the table and prevent further damage. FIG. 7 shows how such a sensor device 37 can be connected to the controller 16, and it is seen that a separate wired connection is needed for connecting the sensor device 37 to the controller 16. However, wires are fragile, which could set the squeeze protection out of order without warning the user. Further, this solution implies additional costs for the wired connection as well as for an additional housing accommodating the sensor device.

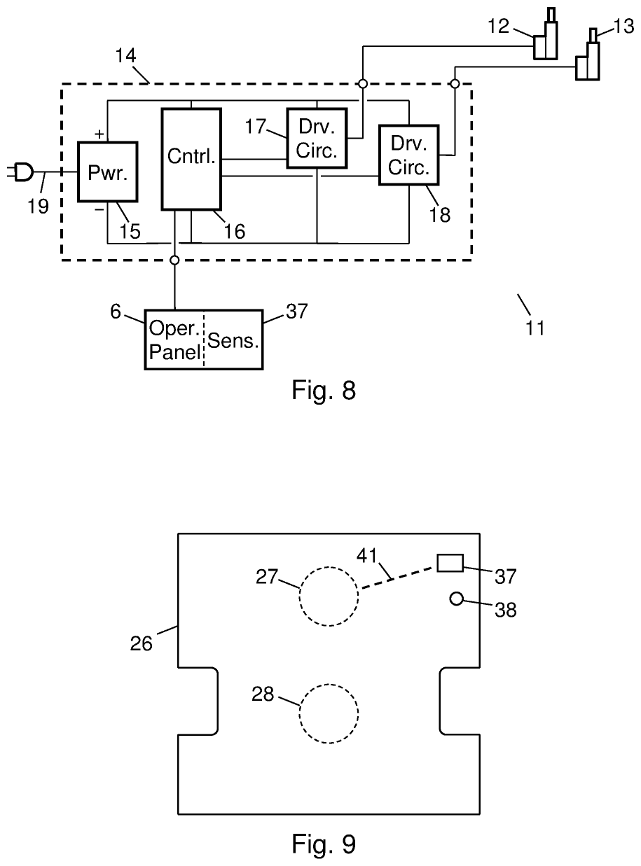

These additional costs can be saved if the sensor device 37 is integrated into the existing housing 21 of the operating panel 6, as it is suggested in FIG. 8. This can be done by mounting the sensor device 37 on the printed circuit board 26, as it is shown in FIG. 9, which also illustrates the positions of the two dome switches 27 and 28 mounted on the opposite side of the printed circuit board 26. To ensure a firm connection between the sensor device 37 and the tabletop 2, a hole 38 arranged in the printed circuit board 26 close to the sensor device 37 allows this part of the printed circuit board (and thus the sensor device 37) to be mechanically firmly connected by e.g. a screw to the housing 21, which is itself firmly connected to the tabletop 2 by e.g. screws through the holes 23. A mechanically firm connection between the sensor device 37 and the tabletop 2 is needed since the purpose of the sensor device is to detect changes in the movement of the tabletop 2. Normally, several other components will be mounted on the printed circuit board 26 for the functions of the operating panel 6 as well as the sensor device 37, but for clarity reasons, these components are not shown in FIG. 9.

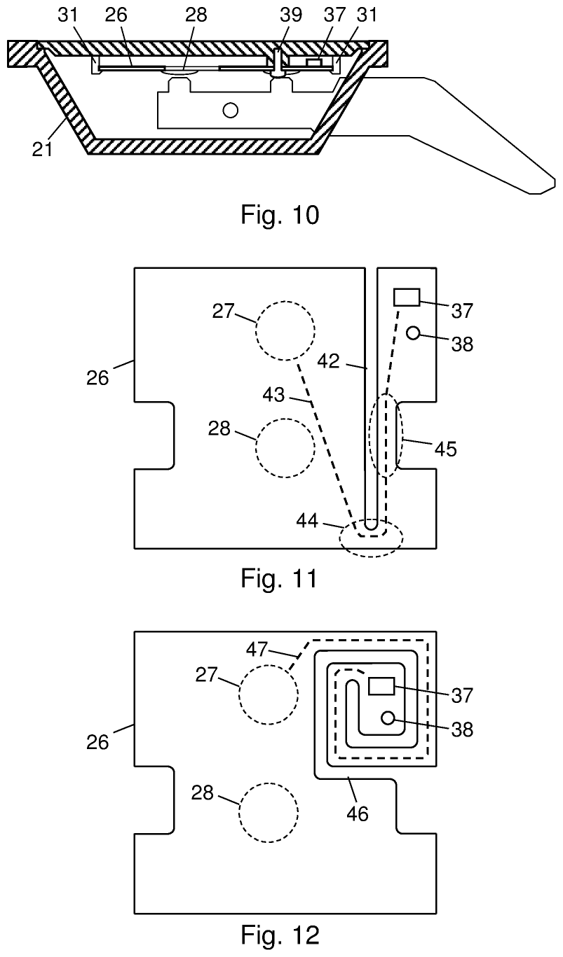

FIG. 10 shows an example of how the printed circuit board 26 with the sensor device 37 and the dome switches 27 and 28 can be arranged in the housing 21. The figure shows a screw 39 that through the hole 38 mentioned above ensures the firm connection between the housing 21 and the section of the printed circuit board 26 on which the sensor device 37 is mounted. It is noted that the other parts of the circuit board 26 are kept in place in the housing 21 by guides 31 arranged in the housing wall, as it was described above in relation to FIG. 5.

However, it has shown that the mechanical operation of the dome switches 27 and 28 can generate a mechanical noise in the form of bending of the printed circuit board 26 or vibrations, or even just bouncing of the contacts of the dome switches. This noise can be transmitted through the printed circuit board 26 and detected by the sensor device 37, which may cause a false detection of squeezing with the result that the adjustment of the table is unintentionally stopped. Thus, if e.g. the dome switch 27 is pressed or released, FIG. 9 illustrates that this mechanical noise can easily propagate in the relatively rigid circuit board from the dome switch 27 to the sensor device 37 along a direct and short mechanical path 41. A similar path can be drawn from the dome switch 28. Of course, this situation can be avoided, or at least mitigated, if the sensor device 37 is arranged in the housing 21 on a separate circuit board connected to the printed circuit board 26 by wires, but this would increase the cost of the system considerably.

FIG. 11 illustrates a different way of avoiding or mitigating this situation. The figure shows that a cut-out 42 is arranged in the printed circuit board 26 between the section of the board on which the dome switches 27 and 28 are mounted and the section of the board on which the sensor device 37 is mounted in such a way that the mechanical path 43 along which the mechanical noise can propagate from e.g. the dome switch 27 to the sensor device 37 in the circuit board is now defined by the cut-out 42. As seen in the figure, the propagating path of the mechanical noise is now considerably longer, which in itself reduces the amount of noise arriving at the sensor device 37, regarding bending as well as vibrations. Further, in the shown example, the rigidness of the printed circuit board is clearly reduced e.g. in the areas 44 and 45 indicated in the figure, which makes the board more flexible in these areas, thereby reducing the transfer of bending and vibrations.

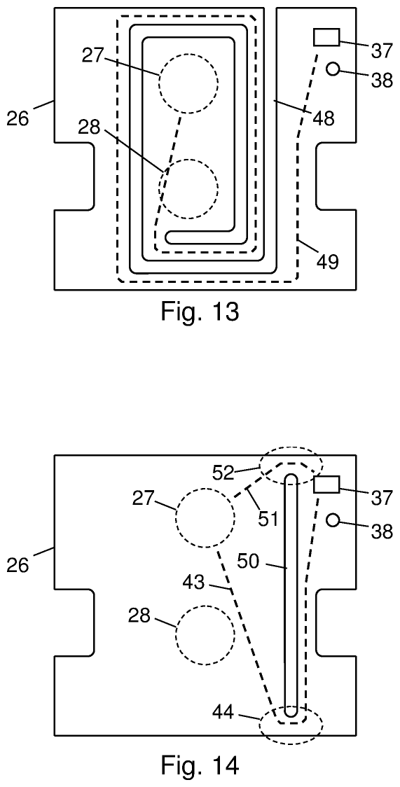

In FIG. 11, the cut-out 42 is a straight cut extending from an edge of the printed circuit board 26 and separating the section with the sensor device 37 from the section with the dome switches 27 and 28. However, the cut-out may also have other forms. An example of this is shown in FIG. 12, in which the cut-out 46 has a spiral like shape. This means that also the continuous mechanical path 47 along which the mechanical noise can propagate from e.g. the dome switch 27 to the sensor device 37 in the circuit board defined by the cut-out 46 has a spiral like shape, as it is seen in the figure. In this embodiment, the mechanical path 47 is relatively long, and further, because of the narrow width of the path, the rigidness of the printed circuit board is clearly reduced along the entire length of the path, which makes the board quite flexible in this area, thereby reducing the transfer of bending and vibrations. In FIG. 12, the sensor device 37 is arranged in the middle of the spiral like shape. However, the spiral like shape can just as well be arranged around the dome switches 27 and 28, as it is shown in FIG. 13, where the cut-out 48 defines the continuous mechanical path 49. The effect of the cut-out is the same as in FIG. 12.

The cut-out does not need to extend from an edge of the printed circuit board as shown in the previous figures, as long as it is arranged so that it separates the section with the sensor device 37 from the section with the dome switches 27 and 28. This is illustrated with the cut-out 50 in FIG. 14. Although the cut-out 50 defines a further (and shorter) mechanical path 51 in addition to the path 43 that was shown in FIG. 11, the rigidness of the printed circuit board is still reduced in the areas 44 and 52 indicated in the figure, which makes the board flexible in these areas, thereby reducing the transfer of bending and vibrations. The reduction in the transfer of bending and vibrations is less than in the embodiment of FIG. 11, but in many situations, and depending on the sensitivity of the sensor device 37, it will be sufficient to prevent a false detection of squeezing.

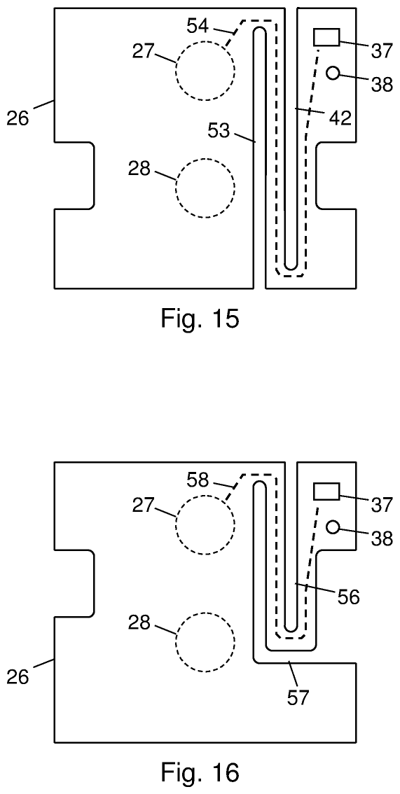

In the previously described embodiments, a single cut-out has been arranged in the printed circuit board 26. FIG. 15 shows an embodiment in which two cut-outs 42 and 53 are used, each one extending from a different edge of the printed circuit board. As seen, the two cut-outs 42 and 53 define a continuous mechanical path 54 having a serpentine like shape along which the mechanical noise can propagate in the circuit board from e.g. the dome switch 27 to the sensor device 37. Similarly to the embodiments of FIGS. 12 and 13, the mechanical path 54 of this embodiment is relatively long, and further, because of the narrow width of the path, the rigidness of the printed circuit board is clearly reduced along the entire length of the path, which makes the board quite flexible in this area, thereby reducing the transfer of bending and vibrations.

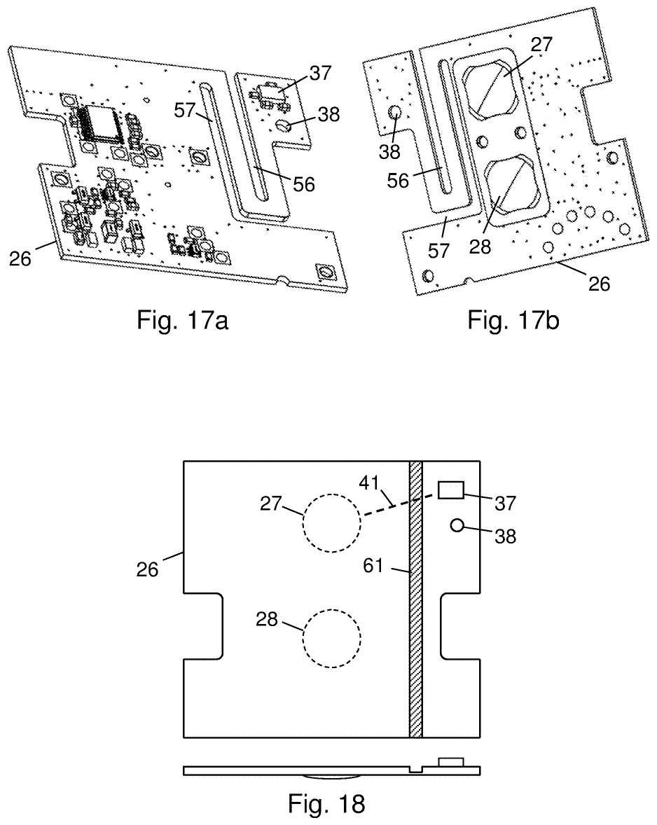

A slightly different embodiment is shown in FIG. 16, in which two cut-outs 56 and 57 are used, each one extending from a different edge of the printed circuit board. Also here, the two cut-outs 56 and 57 define a continuous mechanical path 58 having a serpentine like shape along which the mechanical noise can propagate in the circuit board from e.g. the dome switch 27 to the sensor device 37. Likewise, the mechanical path 58 of this embodiment is relatively long, and, because of the narrow width of the path, the rigidness of the printed circuit board is clearly reduced along the entire length of the path, which makes the board quite flexible in this area, thereby reducing the transfer of bending and vibrations. FIGS. 17a and 17b show perspective views of the printed circuit board 26 of FIG. 16. In these views, a number of further components implementing the functions of the operating panel 6 as well as the sensor device 37 are shown.

The cut-out in the printed circuit board 26 may also have different forms. As an example, FIG. 18 shows a cut-out 61 that reduces the thickness of the printed circuit board 26 in an area between the section of the board on which the dome switches 27 and 28 are mounted and the section of the board on which the sensor device 37 is mounted in such a way that the mechanical path 62 along which the mechanical noise can propagate from e.g. the dome switch 27 to the sensor device 37 in the circuit board is defined by the cut-out 61. Although the mechanical path 62 in this case, as it is also seen in the figure, is only slightly longer than the path 41 in the board 26 of FIG. 9 without cut-outs, due to the reduced thickness of the printed circuit board 26 on a part of the path, i.e. in the area of the cut-out 61, the rigidness of the printed circuit board is considerably reduced, which makes the board quite flexible in this area, thereby reducing the transfer of bending and vibrations.

Other embodiments may use three or more cut-outs for defining a continuous mechanical path in the circuit board from e.g. the dome switch 27 to the sensor device 37.

It is also noted that the different forms of the cut-outs described above may be combined. As an example, one of the cut-outs 42 and 53 in FIG. 15 could be replaced by a cut-out similar to the cut-out 61 shown in FIG. 18.

Although various embodiments of the present invention have been described and shown, the invention is not restricted thereto, but may also be embodied in other ways within the scope of the subject-matter defined in the following claims.

1. A user interface (6) for adjusting an adjustable article of furniture (1) comprising an electric actuator system (11), the user interface (6) comprising:
a housing (21) configured to be firmly fastened mechanically to a movable part (2) of said adjustable article of furniture (1),
a printed circuit board (26) arranged in the housing (21) and comprising a first section and a second section,
at least one mechanically operated switch (27, 28) for activating the adjustment of the adjustable article of furniture (1), said switch (27, 28) being mounted on the first section of said printed circuit board (26), and
an electronic sensor device (37) for detecting mechanical movement, said sensor device (37) being mounted on the second section of said printed circuit board (26), wherein said second section of the printed circuit board (26) is firmly fastened to the housing (21),
wherein the printed circuit board (26) is provided with at least one cut-out (42;
46; 48; 50; 53; 56; 57; 61) arranged between said first section and said second section and defining a continuous mechanical path (43; 47; 49; 51; 54; 58; 62) through the printed circuit board (26) from the at least one mechanically operated switch (27, 28) to the electronic sensor device (37), and
wherein said first section of the printed circuit board (26) is connected mechanically to the housing (21) through said continuous mechanical path and said second section of the printed circuit board (26).

2. A user interface according to claim 1, wherein said continuous mechanical path (43; 47; 49; 51; 54; 58; 62) has a length that is defined by said at least one cut-out.

3. A user interface according to claim 1 or 2, wherein at least a part of said continuous mechanical path (43; 47; 49; 51; 54; 58) has a width that is defined by said at least one cut-out.

4. A user interface according to any one of claims 1 to 3, wherein said printed circuit board (26) on at least a part of said continuous mechanical path (62) has a reduced thickness that is defined by said at least one cut-out (61).

5. A user interface according to any one of claims 1 to 4, wherein said at least one cut-out comprises a single cut-out (42; 46; 48) extending from an edge of said printed circuit board (26).

6. A user interface according to claim 5, wherein said single cut-out (46; 48) extending from an edge of said printed circuit board (26) as well as said continuous mechanical path (47; 49) through the printed circuit board (26) defined by said single cut-out have a spiral like shape.

7. A user interface according to any one of claims 1 to 4, wherein said at least one cut-out comprises two cut-outs (42, 53; 56, 57), each one extending from a different edge of said printed circuit board (26).

8. A user interface according to claim 7, wherein said continuous mechanical path (54; 58) through the printed circuit board defined by said two cut-outs (42, 53; 56, 57) has a serpentine like shape.

9. A user interface according to any one of claims 1 to 8, wherein said electronic sensor device (37) for detecting mechanical movement comprises an accelerometer.

10. A user interface according to any one of claims 1 to 9, wherein said electronic sensor device (37) for detecting mechanical movement comprises a gyroscope.

11. An electric actuator system (11) comprising:
at least one linear actuator (12, 13),
a controller (16) for controlling the at least one linear actuator (12, 13), and
a user interface (6) according to any one of claims 1 to 10 connected to the controller (16).

12. An adjustable article of furniture (1) comprising an electric actuator system (11) according to claim 11.
